(19) United States
(12) Patent Application Publication
(10) Pub. No.: US 2016/0293806 A1
(43) Pub. Date: Oct. 6, 2016

(54) LIGHT-EMITTING DIODE (LED) PACKAGE

(71) Applicant: Genesis Photonics Inc., Tainan City (TW)

(72) Inventors: Hao-Chung Lee, Tainan City (TW); Yu-Feng Lin, Tainan City (TW)

(21) Appl. No.: 15/088,123

(22) Filed: Apr. 1, 2016

(30) Foreign Application Priority Data
Apr. 2, 2015 (TW) 104110882
Jul. 22, 2015 (CN) 201510433655.2

(51) Int. Cl. H01L 33/50; H01L 33/54; F21S 8/10; H01L 33/48

(52) U.S. Cl. CPC H01L 33/502; H01L 33/483; H01L 33/54; F21S 48/115; F21S 48/215; F21Y 2101/02

(57) ABSTRACT

A light-emitting diode (LED) package including a rectangular carrier, an LED chip, and an encapsulant is provided. The rectangular carrier has an upper surface. The LED chip is mounted on the upper surface and is electrically connected to the rectangular carrier. The encapsulant has a curved convex surface and covers the entire upper surface and the LED chip. The encapsulant is doped with a phosphor material for converting at least parts of light emitted from the LED chip. The encapsulant doped with the phosphor material is visually neon orange when the LED chip does not emit the light.

### CROSS-REFERENCE TO RELATED APPLICATION

This application claims the priority benefits of Taiwan application serial no. 104110882, filed on Apr. 2, 2015, and Chinese application serial no. 201510433655.2, filed on Jul. 22, 2015. The entirety of each of the above-mentioned patent applications is hereby incorporated by reference herein and made a part of this specification.

### FIELD OF THE DISCLOSURE

The invention relates to a light-emitting device. In particular, the invention relates to a light-emitting diode (LED) package.

### DESCRIPTION OF RELATED ART

With progress in semiconductor technologies, a light-emitting diode (LED) now has advantages of high luminance and satisfactory color rendering property, low power consumption, compactness, low driving voltage, mercury free, etc.; therefore, the LED has been extensively applied in the fields of displays, vehicle illumination, and so on. For instance, in case of the vehicle illumination, the LED can be applied not only to headlight and tail light but to turn signals. The turn signals of vehicles are required to have colors (e.g., orange-yellow) other than white; hence, how to manufacture the LED with high power and stable color-displaying performance is one of the main concerns of researchers.

### SUMMARY

The invention is directed to a light-emitting diode (LED) package that includes an encapsulant whose height-to-width ratio is appropriate.

In an embodiment of the invention, an LED package including a rectangular carrier, an LED chip, and an encapsulant is provided. The rectangular carrier has an upper surface. The LED chip is mounted on the upper surface and is electrically connected to the rectangular carrier. The encapsulant covers the upper surface and the LED chip. The encapsulant is doped with a phosphor material for converting a wavelength of at least parts of light emitted from the LED chip. The encapsulant has a curved convex surface and covers the entire upper surface. When the LED chip does not emit the light, the encapsulant doped with the phosphor material is visually neon orange.

According to an embodiment of the invention, in a thickness direction of the encapsulant, a maximum height from the curved convex surface to the upper surface is H, a width of the encapsulant is W, and a ratio of H to W is within a range from 0.05 to 0.5.

According to an embodiment of the invention, the rectangular carrier includes a rectangular circuit board, for instance.

According to an embodiment of the invention, the LED chip is electrically connected to the rectangular carrier by flip-chip-bonding, for instance.

According to an embodiment of the invention, a width of the encapsulant is equal to a length of one side of the rectangular carrier or equal to a length of a diagonal of the rectangular carrier.

According to an embodiment of the invention, a distance between the curved convex surface and the upper surface gradually increases from an edge of the rectangular carrier to a center of the rectangular carrier.

According to an embodiment of the invention, an included angle between the curved convex surface and the upper surface exists at an edge of the rectangular carrier and is an acute angle, and the acute angle is within a range from 5 degrees to 75 degrees.

According to an embodiment of the invention, an edge of the encapsulant is aligned to an edge of the rectangular carrier.

According to an embodiment of the invention, a peak wavelength (λₚ) of the light emitted from the light-emitting diode chip is between 435 nanometers and 475 nanometers, and a peak wavelength (λₚ) of light emitted by exciting the phosphor material is between 570 nanometers and 630 nanometers.

According to an embodiment of the invention, the light emitted by the phosphor material accounts for more than 90% in the LED package.

According to an embodiment of the invention, the light emitted from the LED chip and light emitted by exciting the phosphor material are mixed to obtain orange-yellow light. A CIE 1931 chromo coordinate (x,y) of the mixed light satisfies following conditions, for instance:

y≦x6−0.120;

y≧0.390; and

y≧0.790−0.670x.

In an embodiment of the invention, an LED package including a rectangular carrier, an LED chip, and an encapsulant is provided. The rectangular carrier has an upper surface. The LED chip is mounted on the upper surface and is electrically connected to the rectangular carrier. The encapsulant covers the upper surface and the LED chip. The encapsulant is doped with a phosphor material for converting at least 90% of first light emitted from the LED chip into second light. A wavelength of the first light is shorter than a wavelength of the second light. The encapsulant covers the entire upper surface, and a dominant wavelength of light obtained by mixing the first light with the second light is between 585 nanometers and 595 nanometers.

In an embodiment of the invention, an LED package including a rectangular carrier, an LED chip, and an encapsulant is provided. The rectangular carrier has an upper surface. The LED chip is mounted on the upper surface and is electrically connected to the rectangular carrier. The encapsulant covers the upper surface and the LED chip. The encapsulant is doped with a phosphor material for converting first light into second light, and the encapsulant covers the entire upper surface. A CIE 1931 chromo coordinate (x,y) of light generated by mixing the first light with the second light satisfies following conditions:

y≦x−0.120;

y≧0.390; and

y≧0.790−0.670x.

In view of the above, the encapsulant of the LED package provided herein has the curved convex surface and entirely covers the upper surface of the rectangular carrier. Said design allows the bonding area between the encapsulant and the rectangular carrier to be increased, thus enhancing the device reliability of the LED package. In an embodiment of the invention, the encapsulant is doped with the phosphor material which allows most of the first light emitted from the LED chip to be converted into the second light, so as to obtain the orange-yellow light. Thereby, the LED package can be better applied for the purpose of vehicle illumination.

In order to make the aforementioned and other features and advantages of the disclosure more comprehensible, several embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic cross-sectional view illustrating a light-emitting diode (LED) package according to an embodiment of the invention.

FIG. 2 is a schematic three-dimensional view illustrating an LED package according to an embodiment of the invention.

FIG. 3 illustrates a spectrum of an LED package according to an embodiment of the invention.

### DESCRIPTION OF EMBODIMENTS

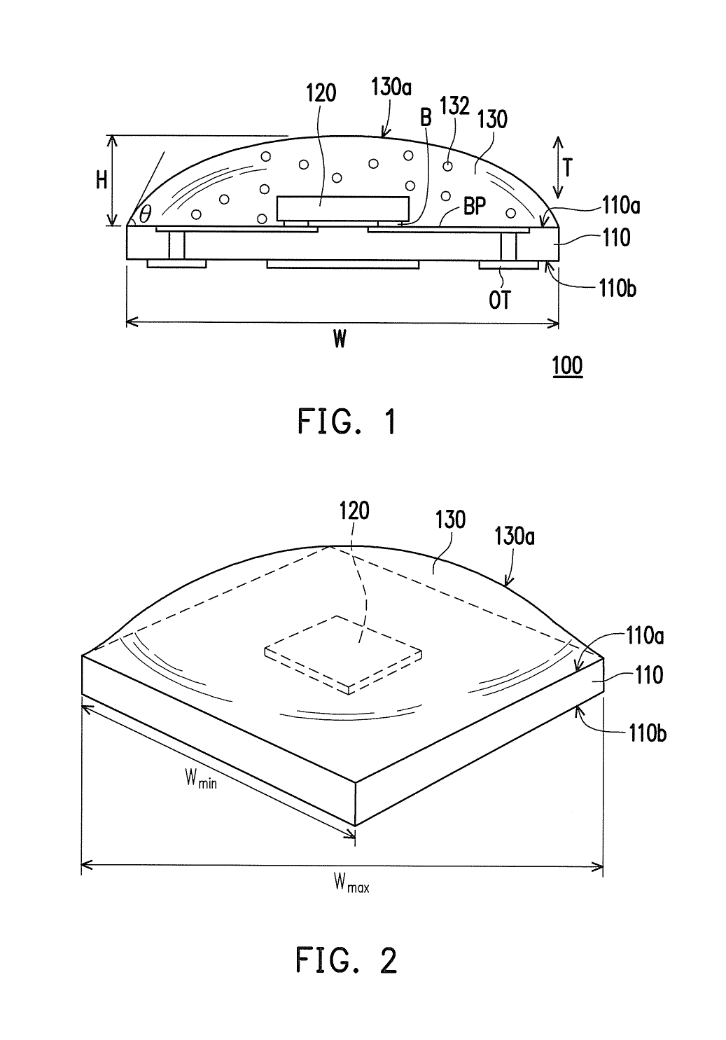

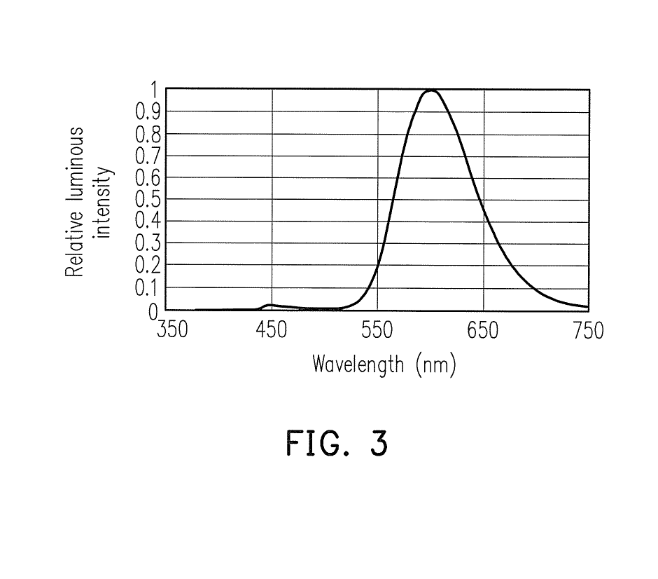

FIG. 1 is a schematic cross-sectional view illustrating a light-emitting diode (LED) package according to an embodiment of the invention. FIG. 2 is a schematic three-dimensional view illustrating an LED package according to an embodiment of the invention. FIG. 3 illustrates a spectrum of an LED package according to an embodiment of the invention.

With reference to FIG. 1 to FIG. 3, an LED package 100 provided herein includes a rectangular carrier 110, an LED chip 120, and an encapsulant 130. The rectangular carrier 110 has an upper surface 110a. The LED chip 120 is mounted on the upper surface 110a and is electrically connected to the rectangular carrier 110. The encapsulant 130 covers the upper surface 110a of the rectangular carrier 110 and the LED chip 120, so as to convert first light L1 emitted from the LED chip into second light L2. Note that a wavelength of the first light L1 is shorter than a wavelength of the second light L2. In the present embodiment, the entire upper surface 110a of the rectangular carrier 110 is covered by the encapsulant 130. The encapsulant 130 has a curved convex surface 130a. In a thickness direction T of the encapsulant 130, a maximum height from the curved convex surface 130a to the upper surface 110a of the rectangular carrier 110 is H, a width of the encapsulant is W, and a ratio of H to W is within a range from 0.05 to 0.5.

According to the present embodiment, the rectangular carrier 110 is a rectangular circuit board, for instance. For instance, the rectangular carrier 110 may be a ceramic circuit board, a metal core printed circuit board (MCPCB), a lead frame, or any other carrier that is suitable for carrying the LED chip 120. The rectangular carrier 110 provided in the present embodiment includes a plurality of circuit layers (not shown), for instance, and the circuit layers are suitable for being electrically connected to the LED chip 120. Besides, the LED chip 120 is electrically connected to the rectangular carrier 110 by flip-chip-bonding, for instance. Particularly, a conductive bump B may be formed on the LED chip 120 or on the rectangular carrier 110 according to the present embodiment, such that the LED chip 120 may be electrically connected to the rectangular carrier 110 via the conductive bump B.

As shown in FIG. 1, in addition to the upper surface 110a, the rectangular carrier 110 has a bottom surface 110b opposite to the upper surface 110a, and the circuit layers in the rectangular carrier 110 can be distributed onto the upper surface 110a, the bottom surface 110b, and the inside of the rectangular carrier 110. In most cases, the circuit layers on the upper surface 10a include a plurality of bonding pads BP electrically connected to the LED chip 120, and the circuit layers on the bottom surface 110b include a plurality of outer contacts OT. The circuit layers (e.g., conductive vias) distributed into the rectangular carrier 110 can be applied to connect the bonding pads BP and the outer contacts OT. Thereby, the LED package 100 can be arranged on other circuit carriers through the outer contacts OT distributed onto the bottom surface 110b of the rectangular carrier 110, such that the LED chip 120 can be electrically connected to other circuit carriers. For instance, the LED package 100 provided in the present embodiment can be a surface mount device (SMD), and the outer contacts OT can be directly fixed onto the circuit carriers via solder.

As shown in FIG. 1 and FIG. 2, the outer shape of the encapsulant 130 provided in the present embodiment is different from that of the lens portion of the conventional LED chip package. Specifically, although the encapsulant 130 has the curved convex surface 130a, the outer profile of the curved convex surface 130a is the same as the outer profile of the rectangular carrier 110; that is, the edge of the encapsulant 130 is aligned to the edge of the rectangular carrier 110. According to the present embodiment, the maximum width Wₘₐₓ of the encapsulant 130 is equal to a length of a diagonal of the rectangular carrier 110, and the minimum width Wₘᵢₙ of the encapsulant 130 is equal to a length of one side of the rectangular carrier 110. For instance, the minimum width Wₘᵢₙ of the encapsulant 130 is equal to a length of a short side of the rectangular carrier 110.

As shown in FIG. 1, a distance between the curved convex surface 130a and the upper surface 110a of the rectangular carrier 110 gradually increases from the edge of the rectangular carrier 110 to the center of the rectangular carrier 110. Besides, an included angle between the curved convex surface 130a and the upper surface 110a exists at the edge of the rectangular carrier 110 and is an acute angle θ, and the acute angle θ is within a range from 5 degrees to 75 degrees, for instance.

The encapsulant 130 provided in the present embodiment is silicone doped with a phosphor material 132, for instance, and a dopant concentration of the phosphor material 132 is within a range from 50% to 60%, for instance. The external quantum efficiency of the encapsulant 130 is within a range from 61% to 63%, for instance. A peak wavelength (λₚ) of the first light L1 emitted from the LED chip 120 is between 435 nanometers and 475 nanometers, for instance. Besides, second light L2 is generated after the first light L1 excites the phosphor material 132, and a peak wavelength (λₚ) of the second light L2 emitted by exciting the phosphor material 132 is between 570 nanometers and 630 nanometers, for instance. Here, the peak wavelength (λₚ) of the first light L1 emitted from the LED chip 120 is defined as a corresponding wavelength of the first light L1 with the maximum intensity according to the spectrum of the first light L1, and the peak wavelength (λₚ) of the second light L2 emitted from the phosphor material 132 is defined as a corresponding wavelength of the second light L2 with the maximum intensity according to the spectrum of the second light L2. That is, the LED chip 120 may be a blue LED chip, and the phosphor material 132 is capable of being excited by blue light and emitting orange-yellow light. Besides, the first light L1 emitted from the LED chip 120 is mostly (e.g., at least 90%) converted into the second light L2; therefore, the second light L2 emitted by exciting the phosphor material 132 accounts for more than 90% in the LED package 100, and the first light L1 emitted from the LED chip 120 accounts for less than 10%, as shown by the spectrum in FIG. 3, for instance. In the present embodiment, the phosphor material 132 is CaₓEu_{y}(Si,Al)₁₂(O,N)₁₆, for instance, wherein x is within a range from 0 to 2.5, and y is within a range from 0.01 to 0.2. Preferably, x is 1.67, and y is 0.08, for instance; additionally, the peak wavelength (λₚ) of the second light L2 emitted by exciting the phosphor material 132 is between 599 nanometers and 610 nanometers, for instance.

In the present embodiment, a dominant wavelength (λ_{d}) of the light obtained by mixing the first light L1 (emitted from the LED chip 120) with the second light L2 (emitted by exciting the phosphor material 132) is between 585 nanometers and 595 nanometers, for instance. Here, after the first light L1 and the second light L2 are mixed, the dominant wavelength (λ_{d}) of the mixed light can be calculated according to the chromo coordinate of the mixed light and the chromo coordinate of a reference illuminant (e.g., an equal-energy white light point W_{E}). The way to calculate the dominant wavelength (λ_{d}) is elaborated below.

Here, the equal-energy white light point W_{E} with the chromo coordinate (0.3333, 0.3333) in the CIE 1931 chromaticity diagram serves as a reference illuminant. Given that the point S represents the light generated by mixing the first light L1 with the second light L2 and has the chromo coordinate (x,y), the point W_{E} and the point S are connected and extended to be intersected with the spectrum locus at a point λ_{d}. The corresponding wavelength of the point λ_{d} (with the chromo coordinate (x_{d},y_{d})) on the spectrum locus is the dominant wavelength (λ_{d}).

According to the present embodiment, the first light L1 emitted from the LED chip 120 and the second light L2 emitted by exciting the phosphor material 132 in the encapsulant 130 are mixed to obtain orange-yellow light. The CIE 1931 chromo coordinate (x,y) of the mixed orange-yellow light satisfies following conditions, for instance:

y≦x−0.120;

y≧0.390; and

y≧0.790−0.670x.

To sum up, the encapsulant of the LED package provided herein has the curved convex surface and entirely covers the upper surface of the rectangular carrier. Said design allows the bonding area between the encapsulant and the rectangular carrier to be increased, thus enhancing the device reliability of the LED package. Moreover, according to the embodiments provided above, the encapsulant is doped with the phosphor material which allows most of the first light emitted from the LED chip to be converted into the second light. The first light is mixed with the second light to obtain the orange-yellow light. Thereby, the LED package can be better applied for the purpose of vehicle illumination.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A light-emitting diode package comprising:
a carrier having a rectangular shape;
a light-emitting diode disposed on the carrier; and
an encapsulant covering the light-emitting diode chip and the entire upper surface of the carrier, the encapsulant being doped with a phosphor material and having a curved convex surface, wherein the encapsulant doped with the phosphor material is visually neon orange when the light-emitting diode does not emit light.

2. The light-emitting diode package of claim 1, wherein the encapsulant has a maximum height H and a width W, wherein a ratio of H to W is within a range from 0.05 to 0.5.

3. The light-emitting diode package of claim 2, wherein the width of the encapsulant is equal to a side length or a diagonal length of the carrier.

4. The light-emitting diode package of claim 1, wherein a distance between the curved convex surface and the upper surface gradually increases from edges to the center of the carrier.

5. The light-emitting diode package of claim 1, wherein an included angle between the curved convex surface of the encapsulant and the upper surface of the carrier at an edge is an acute angle not more than 75 degrees.

6. The light-emitting diode package of claim 1, wherein an edge of the encapsulant is aligned to an edge of the carrier.

7. The light-emitting diode package of claim 1, wherein a peak wavelength of the light emitted from the light-emitting diode chip is between 435 nanometers and 475 nanometers, and a peak wavelength of light emitted by exciting the phosphor material is between 570 nanometers and 630 nanometers.

8. The light-emitting diode package of claim 7, wherein the light emitted by exciting the phosphor material accounts for more than 90% of the total light emitted from the light-emitting diode package.

9. The light-emitting diode package of claim 1, wherein the light color is orange-yellow.

10. The light-emitting diode package of claim 1, wherein a CIE 1931 chromo coordinate (x,y) of the light emitted from the light-emitting diode package satisfies following conditions:
y≦x−0.120;
y≧0.390; and
y≧0.790−0.670x.

11. A light-emitting diode package comprising:
a carrier having a rectangular shape;
a light-emitting diode, configured to emit a first light, disposed on the carrier; and
an encapsulant covering the light-emitting diode chip and the entire upper surface of the carrier, the encapsulant being doped with a phosphor material for converting at least 90% of the first light into a second light, wherein a dominant wavelength of the light obtained by mixing the first light and the second light is between 585 nanometers and 595 nanometers.

12. The light-emitting diode package of claim 11, wherein the encapsulant has a curved convex surface, and has a maximum height H and a width W, wherein a ratio of H to W is within a range from 0.05 to 0.5.

13. The light-emitting diode package of claim 11, wherein the second light accounts for more than 90% of total light emitted from the light-emitting diode package.

14. The light-emitting diode package of claim 13, wherein a peak wavelength of the first light is between 435 nanometers and 475 nanometers, and a peak wavelength of the second light is between 570 nanometers and 630 nanometers.

15. The light-emitting diode package of claim 11, wherein the encapsulant has a curved convex surface, and an included angle between the curved convex surface and the upper surface at an edge of the carrier is an acute angle not more than 75 degrees.

16. A light-emitting diode package comprising:
a carrier having a rectangular shape;
a light-emitting diode, configured to emit a first light, disposed on the carrier; and
an encapsulant covering he light-emitting diode chip and the entire upper surface of the carrier, the encapsulant being doped with a phosphor material for converting the first light into a second light, wherein a CIE 1931 chromo coordinate (x,y) of light emitted from the light-emitting diode package satisfies following conditions:
y≦x−0.120;
y≧0.390; and
y≧0.790−0.670x.

17. The light-emitting diode package of claim 16, wherein the encapsulant has a curved convex surface, and has a maximum height H and a width W, wherein a ratio of H to W is within a range from 0.05 to 0.5.

18. The light-emitting diode package of claim 16, wherein the second light accounts for more than 90% of the total light emitted from the light-emitting diode package.

19. The light-emitting diode package of claim 18, wherein a peak wavelength of the first light is between 435 nanometers and 475 nanometers, and a peak wavelength of the second light is between 570 nanometers and 630 nanometers.

20. The light-emitting diode package of claim 16, wherein the encapsulant has a curved convex surface, an included angle between the curved convex surface and the upper surface at an edge of the carrier is an acute angle not more than 75 degrees.
